(19) United States
(12) Patent Application Publication
(10) Pub. No.: US 2017/0069601 A1
(43) Pub. Date: Mar. 9, 2017

(54) MEMORY DEVICE WITH SEPARATED CAPACITORS

(71) Applicant: SAMSUNG ELECTRONICS CO., LTD., SUWON-SI (KR)

(72) Inventor: MIN-SANG PARK, YONGIN-SI (KR)

(21) Appl. No.: 15/186,157

(22) Filed: Jun. 17, 2016

(30) Foreign Application Priority Data
Sep. 9, 2015 (KR) 10-2015-0127708

(51) Int. Cl. H01L 25/065; H01L 27/108; H01L 49/02; H01L 23/48

(52) U.S. Cl. CPC H01L 25/0657; H01L 23/481; H01L 27/108; H01L 28/40; H01L 2225/06541

(57) ABSTRACT

A memory device with separated capacitors is realized as a multi-chip package in which a first die and a second die are stacked. The first die may be a memory die including a first circuit connected to a memory cell array and driven by a first power voltage and a first ground voltage. A first capacitor may be connected between the first power and ground voltages. The second die may be a capacitor die stacked on the first die and including a second capacitor connected in parallel to the first capacitor of the first die via through-substrate-vias (TSVs).

### CROSS-REFERENCE TO RELATED APPLICATION

This application claims priority under 35 U.S.C. §119 to Korean Patent Application No. 10-2015-0127708, filed on Sep. 9, 2015, in the Korean Intellectual Property Office, the disclosure of which is incorporated by reference herein in its entirety.

### TECHNICAL FIELD

The inventive concept relates to a semiconductor memory device, and more particularly, to a memory device including separated capacitors.

### DISCUSSION OF RELATED ART

High capacity dynamic random-access memory (DRAM) may be realized as a multi-chip package including a plurality of memory dies (or memory layers). Each of the memory dies may include a capacitor connected between a power voltage and a ground voltage for driving internal circuits. The memory die may use a high capacitance capacitor to constantly and stably supply the power voltage.

### SUMMARY

According to an exemplary embodiment of the inventive concept, a memory device includes a first die and a second die. The first die includes a first circuit and a first capacitor. The first capacitor is connected to a first power voltage and a first ground voltage. The first circuit is driven by the first capacitor charged with the first power voltage. The second die is stacked on the first die. The second die includes a second capacitor connected to the first power voltage of the first die via a first TSV and to the first ground voltage of the first die via a second TSV.

According to an exemplary embodiment of the inventive concept, a memory device includes a first die and a second die. The first die includes a first memory cell array and a first circuit. The first circuit is connected to a first power voltage and a first ground voltage. The second die stacked on the first die. The second die includes a second memory cell array and a first capacitor. The first capacitor is connected to the first power voltage of the first die via a first TSV and to the first ground voltage of the first die via a second TSV. The first circuit is driven by the first capacitor charged with the first power voltage.

According to an exemplary embodiment of the inventive concept, a memory device includes a first capacitor, a second capacitor, a first through-substrate-via (TSV), a second TSV and a first circuit. The first capacitor is disposed on a first die. The second capacitor is disposed on a second die. The first TSV and the second TSV connect the first capacitor and the second capacitor in parallel. The first circuit is disposed on the first die and the first circuit is connected to the first capacitor.

### BRIEF DESCRIPTION OF THE DRAWINGS

Exemplary embodiments of the inventive concept will be more clearly understood from the following detailed description taken in conjunction with the accompanying drawings in which:

FIG. 1 is a view of a memory device according to an exemplary embodiment of the inventive concept;

FIG. 2 is a view of a memory device according to an exemplary embodiment of the inventive concept;

FIG. 3 is a view of a memory device according to an exemplary embodiment of the inventive concept;

FIG. 4 is a view of a memory device according to an exemplary embodiment of the inventive concept;

FIG. 5 is a view of a memory device according to an exemplary embodiment of the inventive concept;

FIG. 6 is a view of a memory device according to an exemplary embodiment of the inventive concept;

FIG. 7 is a view of a memory device according to an exemplary embodiment of the inventive concept;

FIG. 8 is a block diagram of a mobile system including a memory device, according to an exemplary embodiment of the inventive concept; and

FIG. 9 is a block diagram of a computing system including a memory device, according to an exemplary embodiment of the inventive concept.

### DETAILED DESCRIPTION OF THE EMBODIMENTS

Hereinafter, the inventive concept will now be described more fully with reference to the accompanying drawings, in which exemplary embodiments of the inventive concept are shown. Like reference numerals in the drawings denote like elements, and a repeated explanation will not be given of overlapping features. Rather, these embodiments are provided so that this disclosure is thorough and complete and fully conveys the inventive concept to those skilled in the art. It should be understood that exemplary embodiments of the inventive concept are to cover all modifications, equivalents, and alternatives falling within the spirit and scope of the inventive concept. In the attached drawings, sizes of structures may be exaggerated for clarity.

The terminology used herein is for describing particular embodiments and is not intended to be limiting of exemplary embodiments. As used herein, the singular forms “a,” “an,” and “the,” are intended to include the plural forms as well, unless the context clearly displays otherwise. A unit, device or module may be implemented as a circuit.

A high capacity dynamic random-access memory (DRAM) may be realized as a multi-chip package including a plurality of memory dies or a plurality of memory layers. The multi-chip package is a semiconductor package that is realized as one package in which a plurality of semiconductor chips or various types of semiconductor chips are stacked. The DRAM may further include a logic die electrically connected to the stacked memory dies. The logic die may provide a signal distribution function of receiving commands, addresses, clocks, and data from a memory controller and providing the received commands, addresses, clocks and data to the memory dies. The logic die may operate as a memory buffer between the memory controller and the memory dies, by performing an interface with the memory controller and buffering all of the commands, addresses, clocks, and data. The logic die and the memory dies exchange signals via through-substrate-vias (TSVs).

In an exemplary embodiment of the inventive concept, the TSV may be constructed from various materials to form various shapes. For example, the TSV may be constructed from a conducting material such as a copper, silver, chromium, molybdenum, aluminium, titanium, manganese or a mixture thereof. Additionally, a cross section of the TSV parallel to the die may be a circle or a square and the TSV may be hollow or solid.

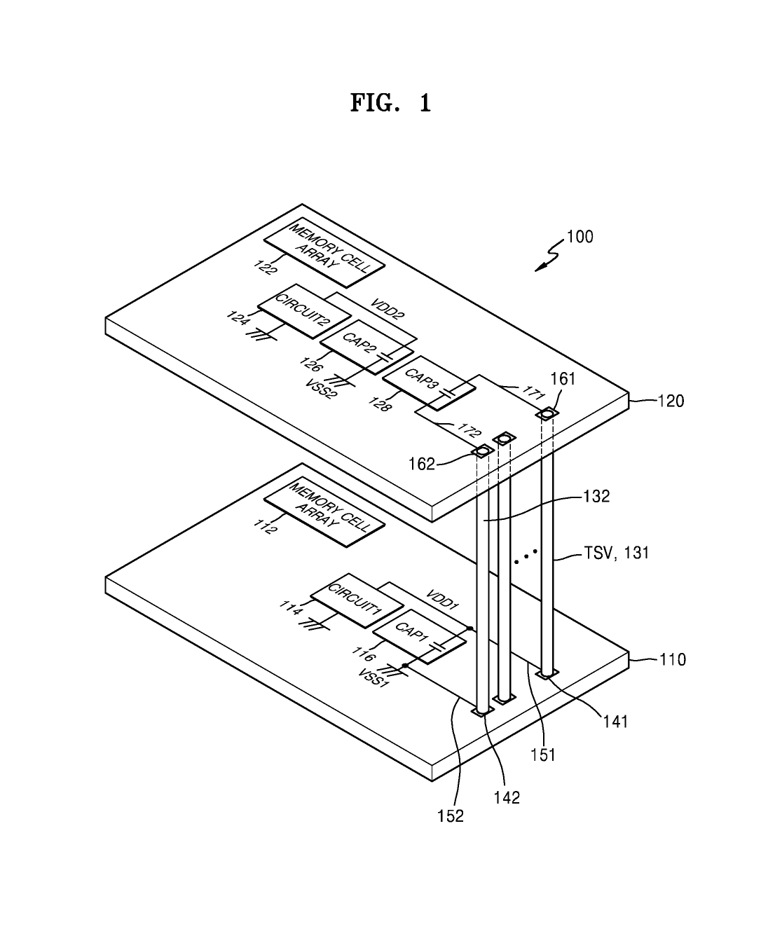

FIG. 1 is a view of a memory device 100 according to an exemplary embodiment of the inventive concept.

Referring to FIG. 1, the memory device 100 may be formed as a multi-chip package including a first die 110 and a second die 120. The first die 110 and the second die 120 may be referred to as memory dies respectively including memory cell arrays 112 and 122.

The first die 110 may include a first circuit 114 and a first capacitor 116. The first power voltage VDD1 and the first ground voltage VSS1 may be connected to the first capacitor 116 and the first capacitor 116 may be charged with the first power voltage VDD1. The first capacitor 116 may provide the first power voltage VDD1 to drive the first circuit 114. The first circuit 114 may be electrically connected to the first memory cell array 112.

The second die 120 may include a second circuit 124 and second and third capacitors 126 and 128. The second power voltage VDD2 and the second ground voltage VSS2 may be connected to the second capacitor 126. The second capacitor 126 may be charged with the second power voltage VDD2. The second capacitor 126 may provide the second power voltage VDD2 to drive the second circuit 124. The second circuit 124 may be electrically connected to the first memory cell array 122.

According to exemplary embodiments, the first power voltage VDD1 and the second power voltage VDD2 may have substantially the same or different voltage levels and the first ground voltage VSS1 and the second ground voltage VSS2 may also have substantially the same or different voltage levels.

The second die 120 is connected to the first die 110 via TSVs 131 and 132. The TSVs 131 and 132 may be connected between conductive pads 141 and 142 of the first die 110 and conductive pads 161 and 162 of the second die 120 to provide an electrical connection between the first die 110 and the second die 120.

The first power voltage VDD1 of the first die 110 is connected to the first conductive pad 141 via a first conductive line 151, and the first ground voltage VSS1 is connected to the second conductive pad 142 via a second conductive line 152. The first power voltage VDD1 and the first ground voltage VSS1 of the first die 110 are connected to the conductive pads 161 and 162 of the second die 120, via the conductive lines 151 and 152, the conductive pads 141 and 142, and the TSVs 131 and 132.

A third capacitor 128 of the second die 120 is connected to the conductive pads 161 and 162 via the first conductive line 171 and the second conductive line 172. The third capacitor 128 is connected in parallel to the first capacitor 116 of the first die 110, via the conductive lines 171 and 172, the conductive pads 161 and 162, and the TSVs 131 and 132. The third capacitor 128 is connected to the first power voltage VDD1 and the first ground voltage VSS1, and is charged with the first power voltage VDD1.

The first circuit 114 of the first die 110 is provided with the first power voltage VDD1 from the first capacitor 116 of the first die 110 and the third capacitor 128 of the second die 120. A capacity of the first capacitor 116 on the first die 110 may be increased to stably provide the first power voltage VDD1 to the first circuit 114. The first die 110 may use the capacitor 128 of the second die 120 via the TSVs 131 and 132 to add additional capacitance to the first capacitor 116 without an increase in chip area.

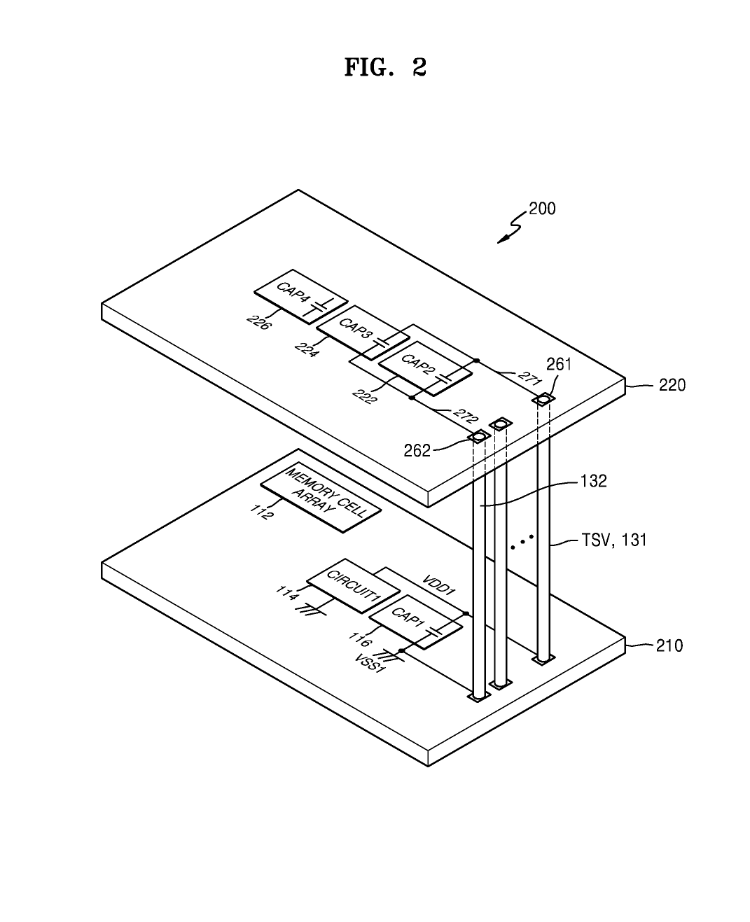

FIG. 2 is a view of a memory device 200 according to an exemplary embodiment of the inventive concept. In FIG. 2, the memory device 200 may be formed as a multi-chip package in which a first die 210 and a second die 220 are stacked. Reference numerals of components of the memory device 200, which correspond to the components of the above-described exemplary embodiments, will be omitted or will be indicated as the same reference numerals.

Referring to FIG. 2, the first die 210 may be a memory die including the memory cell array 112, the first circuit 114, and the first capacitor 116, like the first die 110 of FIG. 1. The first circuit 114 is connected to the first capacitor 116 connected between the first power voltage VDD1 and the first ground voltage VSS1, and is driven by the first power voltage VDD1 charged in the first capacitor 116.

The second die 220 includes second to fourth capacitors 222, 224, and 226. The second die 220 may be a logic die buffering commands, addresses, clocks, and data and transmitting the buffered commands, addresses, clocks, and data to the first die 210. The second and third capacitors 222 and 224 are connected in parallel to each other via conductive lines 271 and 272, and are connected to conductive pads 261 and 262.

According to exemplary embodiments, the second die 220 may be a capacitor die further including a plurality of capacitors, in addition to the second to fourth capacitors 222, 224, and 226. Also, the second to fourth capacitors 222, 224, and 226 may be connected in parallel to one another via the conductive lines 271 and 272.

The conductive pads 261 and 262 of the second die 220 are connected to the first capacitor 116 of the first die 110 via the TSVs 131 and 132. Accordingly, the second and third capacitors 222 and 224 are connected to the first power voltage VDD1 and the first ground voltage VSS1 of the first circuit 114, via the conductive lines 271 and 272, the conductive pads 261 and 262, and the TSVs 131 and 132. The second and third capacitors 222 and 224 are charged with the first power voltage VDD1.

The first capacitor 116 of the first die 210 and the second and third capacitors 222 and 224 of the second die 220 are connected in parallel. The first circuit 114 of the first die 210 is provided with the first power voltage VDD1 from the first capacitor 116 of the first die 210 and the second and third capacitors 222 and 224 of the second die 220.

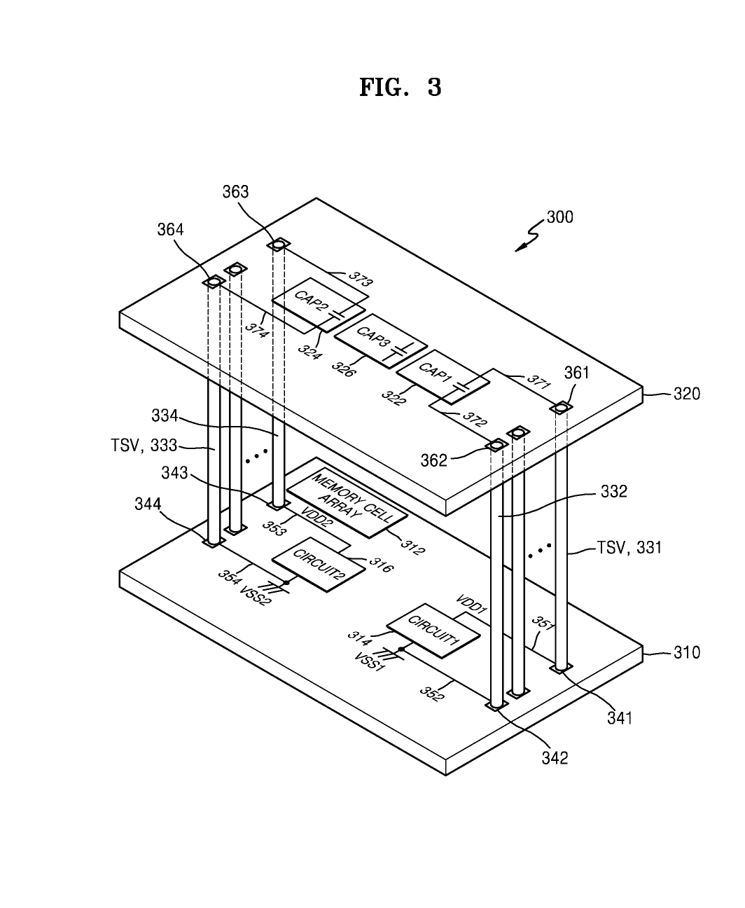

FIG. 3 is a view of a memory device 300 according to an exemplary embodiment of the inventive concept.

Referring to FIG. 3, the memory device 300 may be formed as a multi-chip package in which a first die 310 and a second die 320 are stacked. The first die 310 includes a memory cell array 312 and first and second circuits 314 and 316. The first capacitor 322 is connected to the first power voltage VDD1 and the first ground voltage VSS1 of the first die 310, and is charged with the first power voltage VDD1. The second capacitor 324 is connected to the second power voltage VDD2 and the second ground voltage VSS2 of the first die 310, and is charged with the first power voltage VDD2. The first circuit 314 is driven by a first power voltage VDD1 charged in the first capacitor 322, and the second circuit 316 is driven by a second power voltage VDD2 charged in the second capacitor 324. Each of the first and second circuits 314 and 316 may be connected to the memory cell array 312.

According to an exemplary embodiment of the inventive concept, the first power voltage VDD1 and the second power voltage VDD2, and the first ground voltage VSS1 and the second ground voltage VSS2 may have substantially the same or different voltage levels.

The first power voltage VDD1 of the first die 310 is connected to a first conductive pad 341 via a first conductive line 351, and the first ground voltage VSS1 is connected to a second conductive pad 342 via a second conductive line 352. The conductive pads 341 and 342 of the first die 310 are connected to conductive pads 361 and 362 of the second die 320, via TSVs 331 and 332.

The second power voltage VDD2 of the first die 310 is connected to a third conductive pad 343 via a third conductive line 353, and the second ground voltage VSS2 is connected to a fourth conductive pad 344 via a fourth conductive line 354. The conductive pads 343 and 344 of the first die 310 are connected to conductive pads 363 and 364 of the second die 320 via TSVs 333 and 334.

The second die 320 includes first to third capacitors 322, 324, and 326. The first capacitor 322 is connected to conductive pads 361 and 362 via conductive lines 371 and 372. The first capacitor 322 is connected to the first power voltage VDD1 and the first ground voltage VSS1 of the first die 310 via the conductive lines 371 and 372, the conductive pads 361 and 362, and the TSVs 331 and 332. The first capacitor 322 is charged with the first power voltage VDD1.

The second capacitor 324 of the second die 320 is connected to the conductive pads 363 and 364 via conductive lines 373 and 374. The second capacitor 324 is connected to the second power voltage VDD2 and the second ground voltage VSS2 of the first die 310, via the conductive lines 373 and 374, the conductive pads 363 and 364, and the TSVs 333 and 334. The second capacitor 324 is charged with the second power voltage VDD2.

The first circuit 314 of the first die 310 is provided with the first power voltage VDD1 from the first capacitor 322 of the second die 320, and the second circuit 316 is provided with the second power voltage VDD2 from the second capacitor 324 of the second die 320.

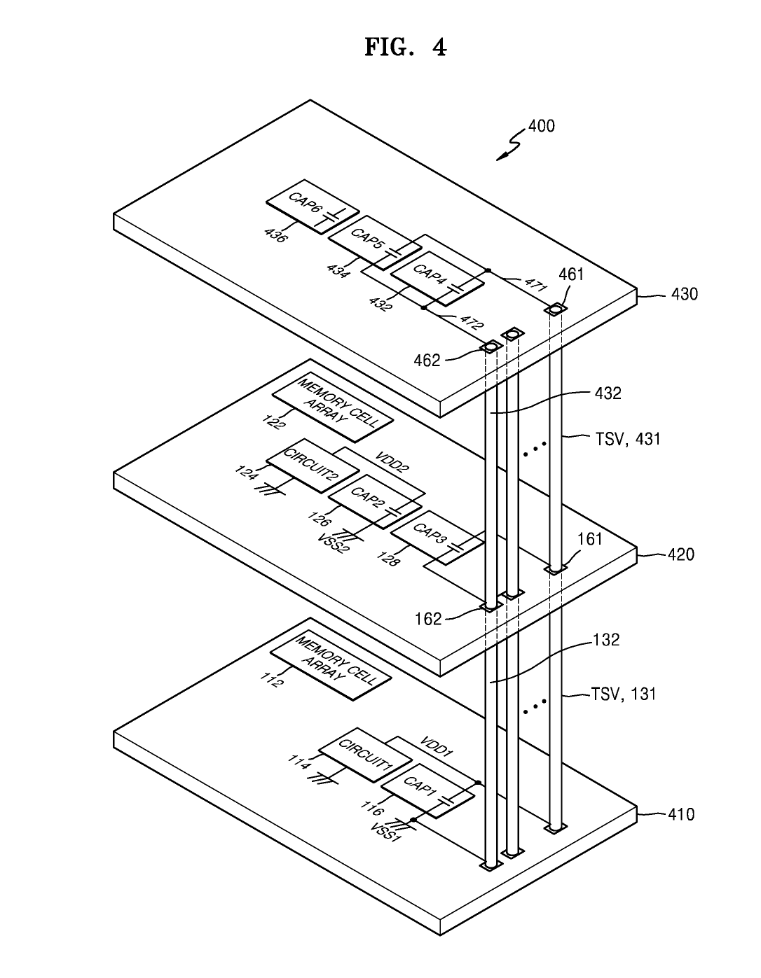

FIG. 4 is a view of a memory device 400 according to an exemplary embodiment of the inventive concept.

Referring to FIG. 4, the memory device 400 is substantially the same as the memory device 100 of FIG. 1. However, the memory device 400 differs from the memory device 100 of FIG. 1 in that the memory device 400 further includes a third die 430 stacked on a second die 420. Reference numerals of components of the memory device 400, which correspond to the components of the above-described exemplary embodiments, will be omitted or will be indicated as the same reference numerals.

A first die 410 includes the memory cell array 112, the first circuit 114, and the first capacitor 116, like the first die 110 of FIG. 1. The first circuit 114 may be connected to the first capacitor 116 connected between the first power voltage VDD1 and the first ground voltage VSS1, and may be driven by the first power voltage VDD1 charged in the first capacitor 116.

The second die 420 includes the memory cell array 122, the second circuit 124, the second capacitor 126, and the third capacitor 128, like the second die 120 of FIG. 1. The second circuit 124 may be connected to the second capacitor 124 connected between the second power voltage VDD2 and the second ground voltage VSS2, and may be driven by the second power voltage VDD2 charged in the second capacitor 126. The third capacitor 128 is connected in parallel to the first capacitor 116 of the first die 410, via the conductive pads 161 and 162 and the TSVs 131 and 132.

The second die 420 is connected to the third die 430 via TSVs 431 and 432. The third die 430 may be a capacitor die including fourth to sixth capacitors 432, 434, and 436. In addition, the third die 430 may be a logic die buffering commands, addresses, clocks, and data and transmitting the buffered commands, addresses, clocks, and data to the first and second dies 410 and 420.

The fourth and fifth capacitors 432 and 434 of the third die 430 are connected in parallel to each other via conductive lines 471 and 472, and are connected to conductive pads 461 and 462. The conductive pads 461 and 462 are connected to the conductive pads 161 and 162 of the second die 420 via the TSVs 431 and 432.

The fourth and fifth capacitors 432 and 434 of the third die 430 are connected in parallel to the third capacitor 128 of the second die 420 and the first capacitor 116 of the first die 410, via the TSVs 431, 432, 131, and 132. The fourth and fifth capacitors 432 and 434 are connected to the first power voltage VDD1 and the first ground voltage VSS1 of the first die 410 and are charged with the first power voltage VDD1.

The first circuit 114 of the first die 410 is provided with the first power voltage VDD1 from the first capacitor 116 of the first die 410, the third capacitor 128 of the second die 420, and the fourth and fifth capacitors 432 and 434 of the third die 430.

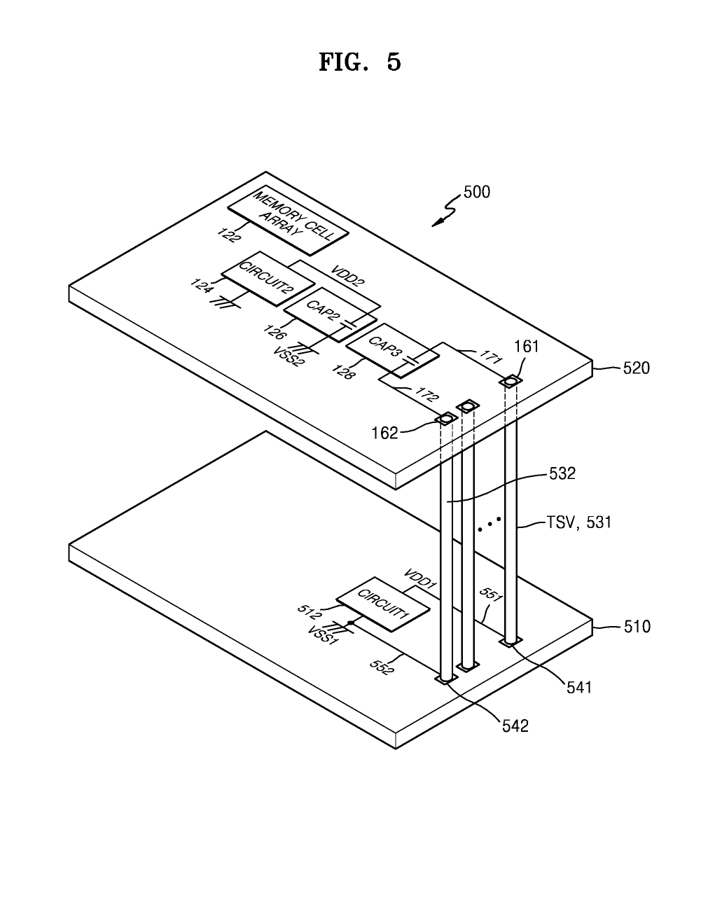

FIG. 5 is a view of a memory device 500 according to an exemplary embodiment of the inventive concept.

Referring to FIG. 5, the memory device 500 is substantially the same as the memory device 100 of FIG. 1. However, the memory device 500 differs from the memory device 100 in that the memory device 500 does not include a memory cell array and a capacitor in a first die 510. Reference numerals of components of the memory device 500, which correspond to the components of the above-described exemplary embodiments, will be omitted or will be indicated as the same reference numerals.

The first die 510 includes a first circuit 512. The first power voltage VDD1 and the first ground voltage VSS1 are connected to conductive pads 541 and 542 via conductive lines 551 and 552. The first die 510 may be a logic die buffering commands, addresses, clocks, and data and transmitting the buffered commands, addresses, clocks, and data to a second die 520.

The second die 520 includes the memory cell array 122, the second circuit 124, the second capacitor 126, and the third capacitor 128, like the second die 120 of FIG. 1. The second circuit 124 may be connected to the second capacitor 126 connected between the second power voltage VDD2 and the second ground voltage VSS2. The second circuit 124 may be driven by the second power voltage VDD2 charged in the second capacitor 126. The third capacitor 128 is connected to the conductive pads 161 and 162 via the conductive lines 171 and 172 and connected to the conductive pads 541 and 542 of the first die 510 via TSVs 531 and 532.

The third capacitor 128 of the second die 520 is connected to the first circuit 512 of the first die 110 via the conductive lines 171 and 172, the conductive pads 161 and 162, and the TSVs 531 and 532. The third capacitor 128 is connected to the first power voltage VDD1 and the first ground voltage VSS1 of the first die 110, and is charged with the first power voltage VDD1. The first circuit 512 is driven by a first power voltage VDD1 charged in the third capacitor 128.

The first circuit 512 of the first die 510 is provided with the first power voltage VDD1 from the third capacitor 128 of the second die 520.

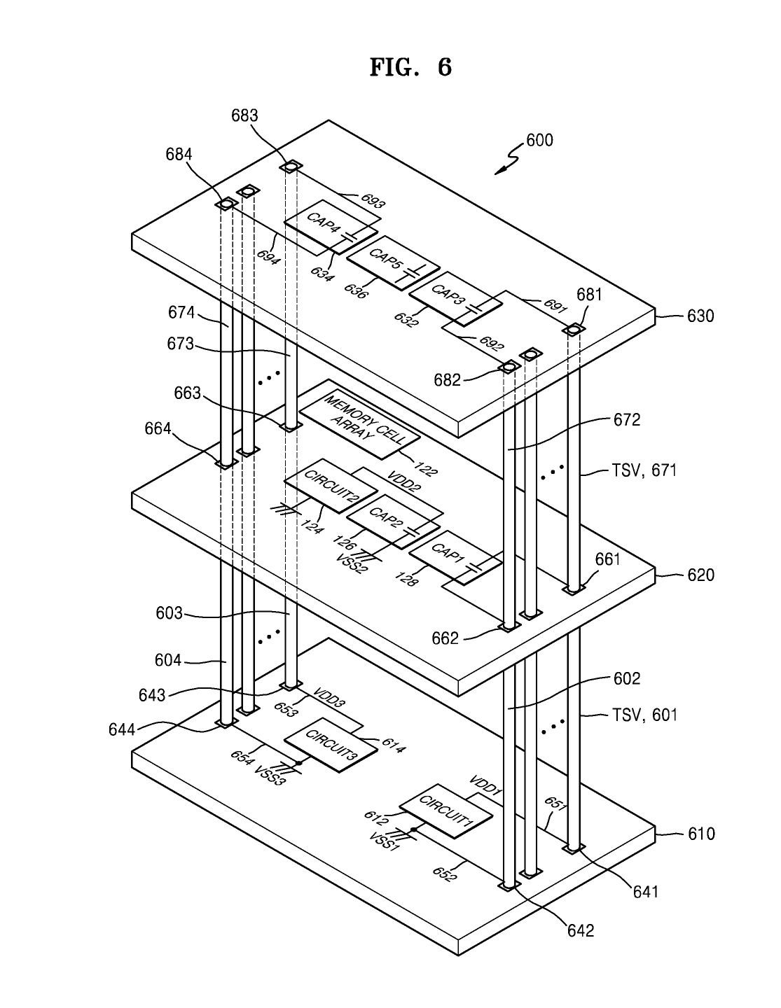

FIG. 6 is a view of a memory device 600 according to an exemplary embodiment of the inventive concept.

Referring to FIG. 6, the memory device 600 may be formed as a multi-chip package in which first to third dies 610 to 630 are stacked. The first die 610 includes a first circuit 612 driven by a first power voltage VDD1 and a first ground voltage VSS1, and a third circuit 614 driven by a third power voltage VDD3 and a third ground voltage VSS3.

According to exemplary embodiments, the first power voltage VDD1, the second power voltage VDD2 and the third power voltage VDD3, and the first ground voltage VSS1, the second ground voltage VSS2 and the third ground voltage VSS3 may have substantially the same or different voltage levels.

The first power voltage VDD1 and the first ground voltage VSS1 are connected to conductive pads 641 and 642 via conductive lines 651 and 652, and the conductive pads 641 and 642 are connected to conductive pads 661 and 662 of the second die 620 via TSVs 601 and 602. The third power voltage VDD3 and the third ground voltage VSS3 are connected to conductive pads 643 and 644 via conductive lines 653 and 654, and the conductive pads 643 and 644 are connected to conductive pads 663 and 664 of the second die 620 via TSVs 603 and 604.

The second die 620 includes the memory cell array 122, the second circuit 124, the first capacitor 128, and the second capacitor 126. The second circuit 124 may be connected to the second capacitor 126 connected between the second power voltage VDD2 and the second ground voltage VSS2, and may be driven by the second power voltage VDD2 charged in the second capacitor 126.

The first capacitor 128 of the second die 620 is connected to the first circuit 612 of the first die 610 via TSVs 601 and 602. The first capacitor 128 is connected to the first power voltage VDD1 and the first ground voltage VSS1 of the first die 110, and is charged with the first power voltage VDD1.

The second die 620 is connected to the third die 630 via TSVs 671, 672, 673, and 674. The third die 630 includes third to fifth capacitors 632, 634, and 636. According to an exemplary embodiment of the inventive concept, the third die 630 may further include a plurality of capacitors, in addition to the third to fifth capacitors 632, 634, and 636.

The third capacitor 632 of the third die 630 is connected to conductive pads 681 and 682 via conductive lines 691 and 692. The conductive pads 681 and 682 are connected to the conductive pads 661 and 662 of the second die 620 via the TSVs 671 and 672. The fourth capacitor 634 of the third die 630 is connected to conductive pads 683 and 684 via conductive lines 693 and 694. The conductive pads 683 and 684 are connected to the conductive pads 663 and 664 of the second die 620 via the TSVs 673 and 674.

The third capacitor 632 of the third die 630 is connected in parallel to the first capacitor 128 of the second die 620 via the TSVs 671, 672, 601, and 602, and is connected to the first circuit 612 of the first die 610. The third capacitor 632 of the third die 630 and the first capacitor 128 of the second die 620 are connected to the first power voltage VDD1 and the first ground voltage VSS1 of the first circuit 612 and are charged with the first power voltage VDD1.

The fourth capacitor 634 of the third die 630 is connected to the third power voltage VDD3 and the third ground voltage VSS3 via the TSVs 673, 674, 603, and 604, and is charged with the third power voltage VDD3. The fourth capacitor 634 of the third die 630 is connected to the third circuit 614 of the first die 610.

The first circuit 612 of the first die 610 is provided with the first power voltage VDD1 from the first capacitor 128 of the second die 620 and the third capacitor 632 of the third die 630. The third circuit 614 of the first die 610 is provided with the third power voltage VDD3 from the fourth capacitor 634 of the third die 630.

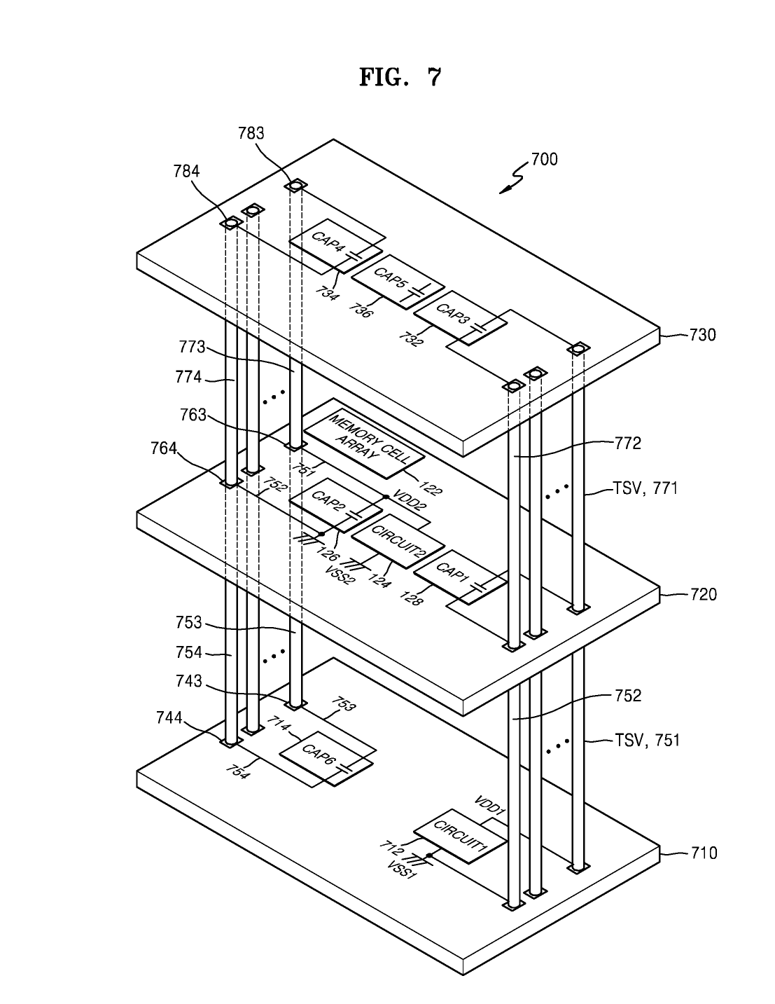

FIG. 7 is a view of a memory device 700 according to an exemplary embodiment of the inventive concept.

Referring to FIG. 7, the memory device 700 is substantially the same as the memory device 600 of FIG. 6. However, the memory device 700 differs from the memory device 600 in that the second capacitor 126 is connected to the second circuit 124 of a second die 720, a sixth capacitor 714 of a first die 710 and the fourth capacitor 734 of a third die 730 in parallel. Reference numerals of components of the memory device 700, which correspond to the components of the above-described exemplary embodiments, will be omitted or will be indicated as the same reference numerals.

The first die 710 includes a first circuit 712 and a sixth capacitor 714. The first circuit 712 is driven by a first power voltage VDD1 and a first ground voltage VSS1. The first circuit 712 is connected to the first capacitor 128 of the second die 720 and the third capacitor 732 of the third die 730, via TSVs 751, 752, 771, and 772. The first capacitor 128 of the second die 720 and the third capacitor 732 of the third die 730 are connected to the first power voltage VDD1 and the first ground voltage VSS1 of the first die 710, and are charged with the first power voltage VDD1. The first circuit 712 of the first die 710 is provided with the first power voltage VDD1 from the first capacitor 128 of the second die 720 and the third capacitor 732 of the third die 730.

The second die 720 includes the memory cell array 122, the second circuit 124, the first capacitor 128, and the second capacitor 126. The second capacitor 126 is connected to the second power voltage VDD2 and the second ground voltage VSS2 of the second die 720, and is charged with the second power voltage VDD2.The second circuit 124 may be connected in parallel with the second capacitor 126. The second circuit 124 may be driven by the second power voltage VDD2 charged in the second capacitor 126.

The second power voltage VDD2 and the second ground voltage VSS2 are connected to conductive pads 763 and 764 via conductive lines 751 and 752. The conductive pads 763 and 764 are connected to conductive pads 743 and 744 of the first die 710 via the TSVs 753 and 754. Additionally, the conductive pads 763 and 764 are connected to conductive pads 783 and 784 of the third die 730 via the TSVs 773 and 774.

The third die 730 includes the third to fifth capacitors 732, 734, and 736. The third capacitor 732 of the third die 730 is connected in parallel to the first capacitor 128 of the second die 720 via the TSVs 771 and 772 and is connected to the first circuit 712 of the first die 710 via the TSVs 751 and 752.

The fourth capacitor 734 of the third die 730 is connected in parallel to the second capacitor 126 of the second die 720 via the TSVs 773 and 774 and the sixth capacitor 714 of the first die 710 via the TSVs 753 and 754. The second capacitor 126 is connected to the second power voltage VDD2 and the second ground voltage VSS2 of the second die 720 to charge the second capacitor 126, the fourth capacitor 734, and the sixth capacitor 714 with the second power voltage VDD2.

The first circuit 712 of the first die 710 is provided with the first power voltage VDD1 from the first capacitor 128 of the second die 720 and the third capacitor 732 of the third die 730. The second circuit 124 of the second die 720 is provided with the second power voltage VDD2 from the second capacitor 126 of the second die 720, the sixth capacitor 714 of the first die 710, and the fourth capacitor 734 of the third die 730.

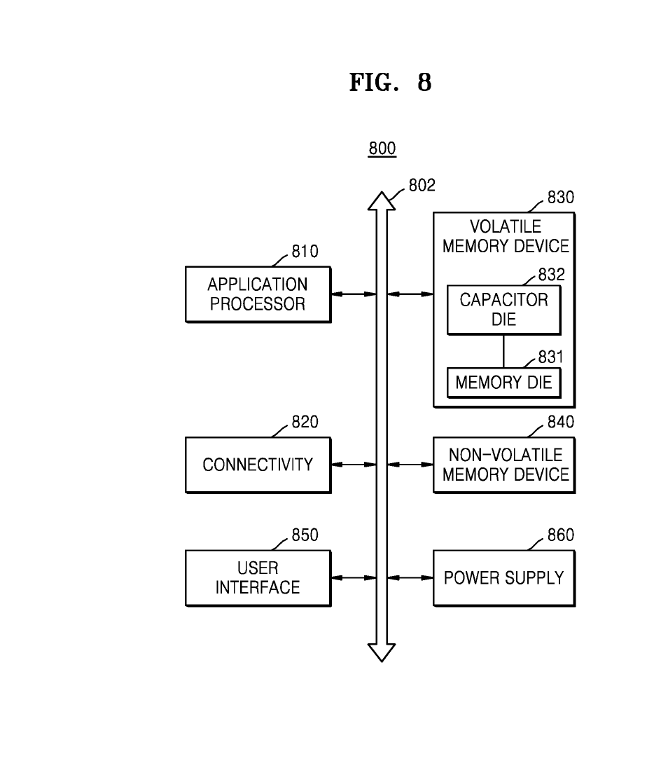

FIG. 8 is a block diagram of an example of a mobile system 800, in which memory devices 830 and 840 having separated capacitors are included, according to an exemplary embodiment of the inventive concept.

Referring to FIG. 8, the mobile system 800 may include an application processor 810, a connectivity unit 820, the first memory device 830, the second memory device 840, a user interface 850, and a power supply 860, which are connected to one another via a bus 802. The first memory device 830 may be a volatile memory device, and the second memory device 840 may be a non-volatile memory device. According to an exemplary embodiment of the inventive concept, the mobile system 800 may be a mobile system, such as a mobile phone, a smart phone, a personal digital assistant (PDA), a portable multimedia player (PMP), a digital camera, a music player, a portable game console, a navigation system, etc.

The application processor 810 may execute applications including an internet browser, a game, a video, etc. According to an exemplary embodiment the inventive concept, the application processor 810 may include a single core processor or a multi-core processor. For example, the application processor 810 may include a dual-core processor, a quid-core processor, or a hexa-core processor. Also, according to an exemplary embodiment, the application processor 810 may further include a cache memory located inside or outside the application processor 810.

The connectivity unit 820 may perform wireless or wired communication with external devices. For example, the connectivity unit 820 may communicate via Ethernet communication, near field communication (NFC), radio frequency identification (RFID) communication, mobile telecommunication, memory card communication, universal serial bus (USB) communication, etc. Additionally, the connectivity unit 820 may include a baseband chipset, and may support communication standards, including global system for mobile communications (GSM), general packet radio service (GPRS), wideband code division multiple access (WCDMA), or HSxPA.

The first memory device 830, which may be a volatile memory device, may store data processed by the application processor 810 as write data, or may operate as a working memory. The first memory device 830 is realized as a multi-chip package in which a first die 831 and a second die 832 are stacked. The first die 831 may be a memory die including a first circuit connected to a memory cell array, and a first capacitor connected between the first power voltage and the first ground voltage. The second die 832 may be a capacitor die stacked on the first die 831 and may include a second capacitor connected in parallel to the first capacitor of the first die 831 via TSVs. The second capacitor of the second die 832 may be connected to the power voltage and the first ground voltage. The first circuit may be driven by the first power voltage charged in the first capacitor and the second capacitor. The stacked first and second capacitors of the memory device 830 may constantly and stably supply a power voltage without an increase in a chip area of the memory device 830.

The second memory device 840, which is a non-volatile memory device, may store a boot image for booting the mobile system 800. For example, the non-volatile memory device 840 may be realized as electrically erasable programmable read-only memory (EEPROM), flash memory, phase change random access memory (PRAM), resistance random access memory (RRAM), nano-floating gate memory (NFGM), polymer random access memory (PoRAM), magnetic random access memory (MRAM), ferroelectric random access memory (FRAM), or the like.

The user interface 850 may include at least one input device such as a keypad and a touch screen, and/or a speaker, a display device, and at least one output device.

The power supply 860 may supply an operation voltage of the mobile system 800.

Also, according to exemplary embodiments, the mobile system 800 may further include a camera image processor (CIP), and a storage device, such as a memory card, a solid state drive (SSD), a hard disk drive (HDD), a CD-ROM, etc.

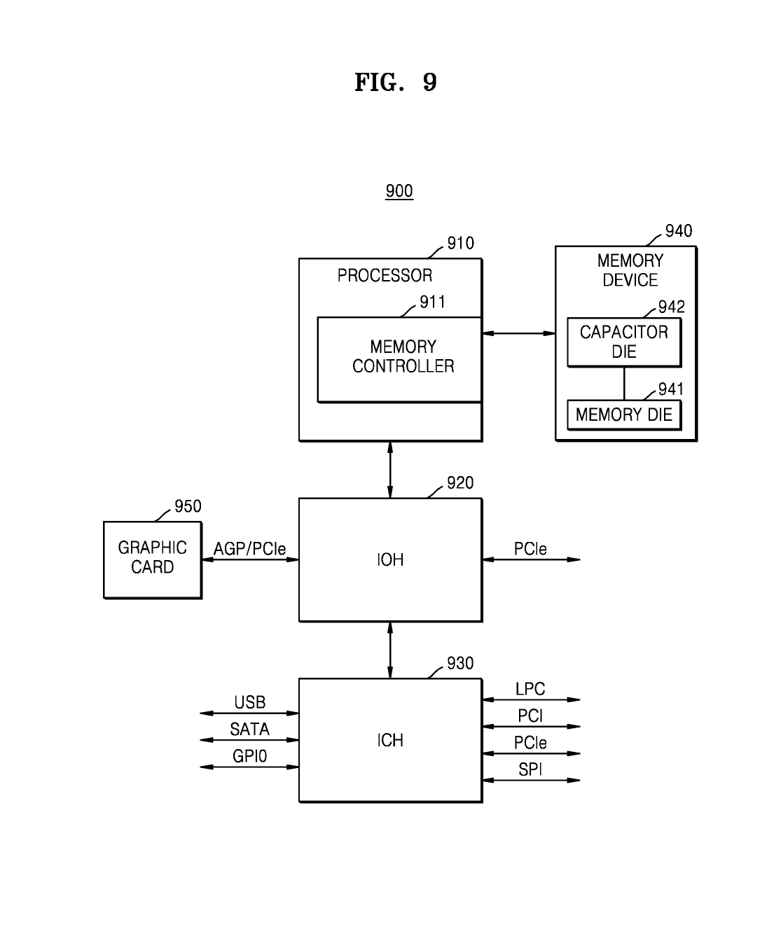

FIG. 9 is a block diagram of a computing system 900, in which a memory device 940 with separated capacitors is included, according to an exemplary embodiment of the inventive concept.

Referring to FIG. 9, the computing system 900 includes a processor 910, an input/output hub (IOH) 920, an input/output controller hub (ICH) 930, the memory device 940, and a graphics card 950. According to an exemplary embodiment of the inventive concept, the computing system 900 may be a computing system, such as a personal computer (PC), a server computer, a workstation, a laptop computer, a mobile phone, a smart phone, a personal digital assistant (PDA), a portable multimedia player (PMP), a digital camera, a digital television (TV), a set-top box, a music player, a portable game console, a navigation system, etc.

The processor 910 may perform various computing functions, such as calculations or tasks. For example, the processor 910 may be a microprocessor or a central processing unit (CPU). According to an exemplary embodiment of the inventive concept, the processor 910 may include a single-core processor or a multi-core processor. For example, the processor 910 may include a dual-core processor, a quad-core processor, or a hexa-core processor. Also, although FIG. 9 illustrates the computing system 900 including one processor 910, the computing system 900 may include a plurality of processors according to an exemplary embodiment. According to an exemplary embodiment of the inventive concept, the processor 910 may further include a cache memory located inside or outside the processor 910.

The processor 910 may include a memory controller 911 controlling an operation of the memory device 940. The memory controller 911 included in the processor 910 may be called an integrated memory controller (IMC). According to an exemplary embodiment of the inventive concept, the memory controller 911 may be located in the input/output hub 920. The input/output hub 920 including the memory controller 911 may be called a memory controller hub (MCH).

The memory device 940 may be realized as a multi-chip package in which a first die 941 and a second die 942 are stacked. The first die 941 may be a memory die including a first circuit connected to a memory cell array, and a first capacitor connected between the first power voltage and the first ground voltage. The second die 942 may be a capacitor die stacked on the first die 941 and may include a second capacitor connected in parallel to the first capacitor of the first die 941 via TSVs. The second capacitor of the second die 942 may be connected to the power voltage and the first ground voltage. The first circuit may be driven by the first power voltage charged in the first capacitor and the second capacitor. The stacked first and second capacitors of the memory device 940 may constantly and stably supply a power voltage without an increase in a chip area of the memory device 940.

The input/output hub 920 may manage data transmission between devices such as the graphics card 950 and the processor 910. The input/output hub 920 may be connected to the processor 910 via various types of interfaces. For example, the input/output hub 920 and the processor 910 may be connected to each other via interfaces of various standards, such as a front-side bus (FSB), a system bus, HyperTransport or Lighting Data Transport (LDT), QuickPath Interconnect (QPI), Common System Interface (CSI), Peripheral Component Interconnect Express (PCIe), etc. Although FIG. 9 illustrates the computing system 900 including one input/output hub 920, the computing system 900 may include a plurality of input/output hubs, according to exemplary embodiments.

The input/output hub 920 may provide various interfaces with devices. For example, the input/output hub 920 may provide an accelerated graphics port (AGP) interface, a peripheral component interface-express (PCIe), a communications streaming architecture (CSA) interface, etc.

The graphics card 950 may be connected to the input/output hub 920 via the AGP or the PCIe. The graphics card 950 may control a display device for displaying an image. The graphics card 950 may include an internal processor for processing image data and an internal semiconductor memory device. According to an exemplary embodiment of the inventive concept, the input/output hub 920 may include a graphics device inside the input/output hub 920, together with the graphics card 950 outside the input/output hub 920, or the input/output hub 920 may include the graphics device instead of the graphics card 950. The graphics device included in the input/output hub 920 may be called integrated graphics. Also, the input/output hub 920 including a memory controller and the graphics device may be called a graphics and memory controller hub (GMCH). Additionally, the processor 910 may include a graphics device with or without a separate graphics card 950.

The input/output controller hub 930 may perform data buffering and interface intervention so that various system interfaces efficiently operate. The input/output controller hub 930 may be connected to the input/output hub 920 via an internal bus. For example, the input/output hub 920 and the input/output controller hub 930 may be connected to each other via a direct media interface (DMI), a hub interface, an enterprise south bridge interface (ESI), a PCIe, etc.

The input/output controller hub 930 may provide various interfaces with peripheral devices. For example, the input/output controller hub 930 may provide a universal serial bus (USB) port, a serial advanced technology attachment (SATA) port, a general purpose input/output (GPIO), a low pin count (LPC) bus, a serial peripheral interface (SPI), a peripheral component interface (PCI), a PCIe, etc.

According to an exemplary embodiment of the inventive concept, at least two of the processor 910, the input/output hub 920, and the input/output controller 930 may be realized as one chipset.

While the inventive concept has been particularly shown and described with reference to exemplary embodiments thereof, it will be understood that various changes in form and details may be made therein without departing from the spirit and scope of the following claims.

What is claimed is:

1. A memory device comprising:
a first die comprising a first circuit and a first capacitor, wherein the first capacitor is connected to a first power voltage and a first ground voltage and the first circuit is driven by the first capacitor charged with the first power voltage; and
a second die stacked on the first die and the second die comprising a second capacitor connected to the first power voltage of the first die via a first through-substrate-via (TSV) and to the first ground voltage of the first die via a second TSV.

2. The memory device of claim 1, wherein the second die further comprises a second circuit and a third capacitor, wherein the second circuit is driven by a second power voltage and a second ground voltage and the third capacitor is connected between the second power voltage and the second ground voltage.

3. The memory device of claim 1, wherein the second die further comprises a fourth capacitor connected in parallel to the second capacitor.

4. The memory device of claim 1, wherein the first die further comprises a memory cell array comprising a plurality of memory cells.

5. The memory device of claim 1, wherein the first circuit of the first die operates as an interface between the memory device and an external device.

6. The memory device of claim 1, wherein the second die further comprises a memory cell array comprising a plurality of memory cells.

7. The memory device of claim 1, wherein the memory device further comprises a third die stacked on the second die and comprising a fifth capacitor connected in parallel to the second capacitor of the second die via a third and a fourth TSV, and
the first capacitor of the first die, the second capacitor of the second die, and the fifth capacitor of the third die are charged with the first power voltage.

8. The memory device of claim 7, wherein the third die further comprises a sixth capacitor connected in parallel to the fifth capacitor.

9. A memory device comprising:
a first die comprising a first memory cell array and a first circuit, wherein the first circuit is connected to a first power voltage and a first ground voltage; and
a second die stacked on the first die and the second die comprising a second memory cell array and a first capacitor, wherein the first capacitor is connected to the first power voltage of the first die via a first through-substrate-via (TSV) and to the first ground voltage of the first die via a second TSV, and
wherein the first circuit is driven by the first capacitor charged with the first power voltage.

10. The memory device of claim 9, wherein the first die further comprises a second circuit connected to the first memory cell array and driven by a second power voltage and a second ground voltage, and
the second die further comprises a second capacitor connected to the second power voltage of the first die via a third TSV and to the second ground voltage of the first die via a fourth TSV.

11. The memory device of claim 9, wherein the memory device further comprises a third die stacked on the second die and comprising a third capacitor connected in parallel to the first capacitor of the second die via a fifth and a sixth TSV, and
the first capacitor of the second die and the third capacitor of the third die are charged with the first power voltage of the first die.

12. The memory device of claim 11, wherein the third die further comprises a fourth capacitor connected in parallel to the third capacitor.

13. The memory device of claim 9, wherein the second die further comprises a third circuit connected to the second memory cell array and driven by a third power voltage and a third ground voltage, and
the first die further comprises a fifth capacitor connected to the third power voltage of the second die via a sixth TSV and connected to the third ground voltage of the second die via a seventh TSV.

14. The memory device of claim 13, wherein the memory device further comprises a third die stacked on the second die and comprising a sixth capacitor connected to the third power voltage of the second die via an eighth TSV and to the third ground voltage of the second die via a ninth TSV, and
the fifth capacitor of the first die and the sixth capacitor of the third die are connected in parallel to each other and are charged with the third power voltage.

15. The memory device of claim 14, wherein the third die further comprises a seventh capacitor connected in parallel to the sixth capacitor.

16. A memory device comprising:
a first capacitor disposed on a first die;
a second capacitor disposed on a second die;
a first through-substrate-via (TSV) and a second TSV connecting the first capacitor and the second capacitor in parallel; and
a first circuit disposed on the first die wherein the first circuit is connected to the first capacitor.

17. The memory device of claim 16, wherein the second die includes a plurality of capacitors.

18. The memory device of claim 16, wherein the first circuit is electrically connected to a first memory cell array.

19. The memory device of claim 16, wherein the first circuit, the first capacitor and the second capacitor are connected in parallel.

20. The memory device of claim 19, wherein a third capacitor disposed on a third die is connected in parallel to the second capacitor of the second die via a third and a fourth TSV, and
the first capacitor of the first die, the second capacitor of the second die, and the third capacitor of the third die are charged with the first power voltage.
